(19) United States
(12) Patent Application Publication
(10) Pub. No.: US 2008/0081448 A1
(43) Pub. Date: Apr. 3, 2008

(54) Method for fabricating semiconductor device

(76) Inventors: Jung-Seock Lee, Kyoungki-do (KR); Ky-Hyun Han, Kyoungki-do (KR)

Correspondence Address: BLAKELY SOKOLOFF TAYLOR & ZAFMAN, 1279 OAKMEAD PARKWAY, SUNNYVALE, CA, 94085-4040, US

(21) Appl. No.: 11/823,773

(22) Filed: Jun. 28, 2007

(30) Foreign Application Priority Data
Sep. 29, 2006 (KR) 2006-0096445

(51) Int. Cl. H01L 21/3205

(52) U.S. Cl. 438/589; 257/E21.258; 257/E21.295

(57) ABSTRACT

A method for fabricating a semiconductor device includes forming an insulation layer, a first electrode layer, a second electrode layer, and a hard mask over a substrate, etching the second electrode layer to form second electrodes with recessed sidewalls, forming a passivation layer over a resultant surface profile provided after forming the second electrodes, performing an etch-back process on the passivation layer, and etching the first electrode layer exposed by the etch-back process to form first electrodes.

### CROSS-REFERENCE TO RELATED APPLICATIONS

The present invention claims priority of Korean patent application number 10-2006-0096445, filed on Sep. 29, 2006 which is incorporated by reference in its entirety.

### BACKGROUND OF THE INVENTION

The present invention relates to a method for fabricating a semiconductor device, and more particularly to a method for forming a gate structure of a semiconductor device.

In typical gate structures having metal electrodes, if a gate oxide layer serving a role as a pathway of electrons is used when a gate structure having a metal electrode is formed, it may be difficult to maintain a high quality of the gate oxide layer. Also, if a metal electrode is formed directly over the gate oxide layer, it may be disadvantageous for resistance. Accordingly, it is suggested to form a polysilicon electrode over the gate oxide layer and then, a metal electrode (e.g., tungsten electrode) over the polysilicon electrode.

During a patterning process to form the gate structures, oxygen used after etching the metal electrode (e.g., tungsten electrode) to etch a polysilicon electrode, and a gate re-oxidation generated via a subsequent cleaning process cause abnormal oxidation in the metal electrode. As a result, volume of the metal electrode may be increased. Thus, after the patterning process to form the metal electrode, a passivation layer, which is usually formed of nitride, is formed on the metal electrode, and subsequent processes are performed thereafter.

FIG. 1 illustrates a typical gate structure of a semiconductor device. An isolation structure 12 is formed in a substrate 11 to define an active region, and a plurality of recessed channel regions 13 are formed in the substrate 11. A gate insulation layer 14 is formed on the resulting structure including the recessed channel regions 13. A plurality of gate structures are formed on the gate insulation layer 14. A first portion of each of the gate structures fills the individual recessed channel regions 13 and a second portion thereof projects over the substrate 11. Each of the gate structures includes a polysilicon electrode 15, a metal electrode 16, and a gate hard mask 17, which are formed over the substrate 11 in sequence.

A passivation layer 18 is formed on sidewalls of the gate structures. The passivation layer 18 protects the metal electrodes 16 during formation of the polysilicon electrodes 15 and a subsequent gate re-oxidation process, so that abnormal oxidation does not occur in the metal electrodes 16. For this reason, the passivation layer 18 is formed on sidewalls of the gate hard masks 17 and the metal electrodes 16, and a portion of the polysilicon electrodes 15.

As described above, the polysilicon electrodes 15 below the metal electrodes 16 are etched after protecting the metal electrodes 16 by forming the passivation layer 18 on the sidewalls of the typical gate structures. However, widths of the polysilicon electrodes 15 are increased to the added widths of the metal electrodes 16 and the passivation layer 18. Reference letter W illustrates how much the widths of the polysilicon electrodes 15 are increased. As a result, when subsequent landing plug contacts are formed, an open margin 100 may be reduced due to the reduced space between the polysilicon electrodes 15.

If the width of the passivation layer 18 is decreased to prevent the reduction in the open margin 100, sidewalls of the passivation layer 18 are likely to be etched when the polysilicon electrodes 15 are etched. As a result, the metal electrodes 16 may be exposed and accordingly, the abnormal oxidation may be generated.

### SUMMARY OF THE INVENTION

Embodiments of the present invention are directed toward providing a method for fabricating a semiconductor device, wherein the method can reduce abnormal oxidation that may be generated in a metal electrode and prevent an open margin of a landing plug contact from being reduced due to an increased width of a polysilicon electrode.

In accordance with an aspect of the present invention, there is provided a method for fabricating a semiconductor device. The method includes forming an insulation layer, a first electrode layer, a second electrode layer, and a hard mask over a substrate, etching the second electrode layer to form second electrodes with recessed sidewalls, forming a passivation layer over a resultant surface profile provided after forming the second electrodes, performing an etch-back process on the passivation layer, and etching the first electrode layer exposed by the etch-back process to form first electrodes.

### BRIEF DESCRIPTION OF THE DRAWINGS

FIG. 1 illustrates a typical gate structure of a semiconductor device.

FIGS. 2A to 2F illustrate a method for fabricating a semiconductor device in accordance with an embodiment of the present invention.

FIG. 3 illustrates a gate structure of a semiconductor device in accordance with another embodiment of the present invention.

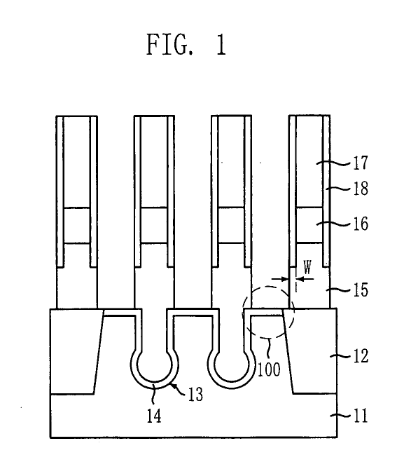

### DESCRIPTION OF SPECIFIC EMBODIMENTS

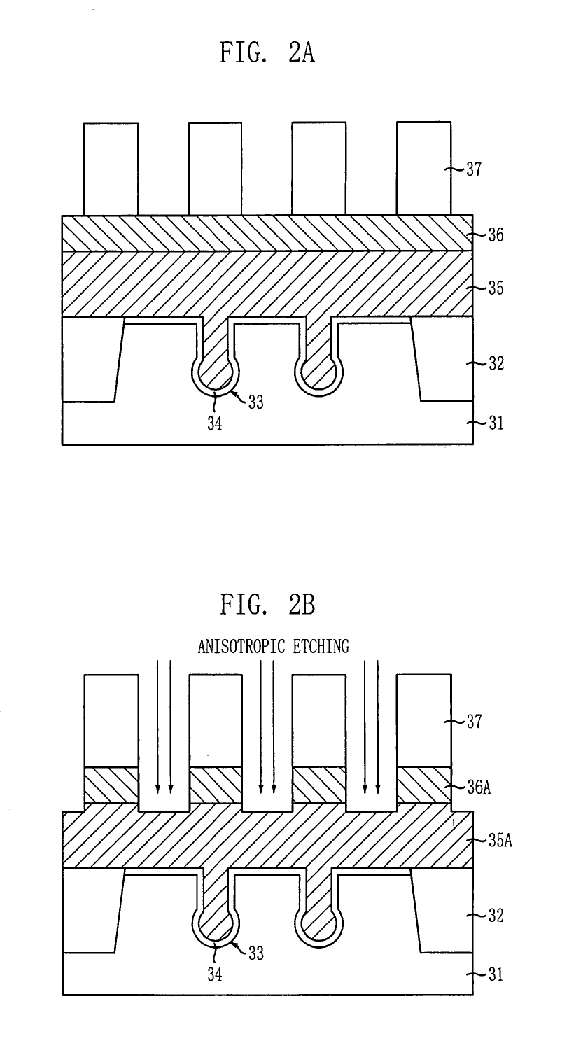

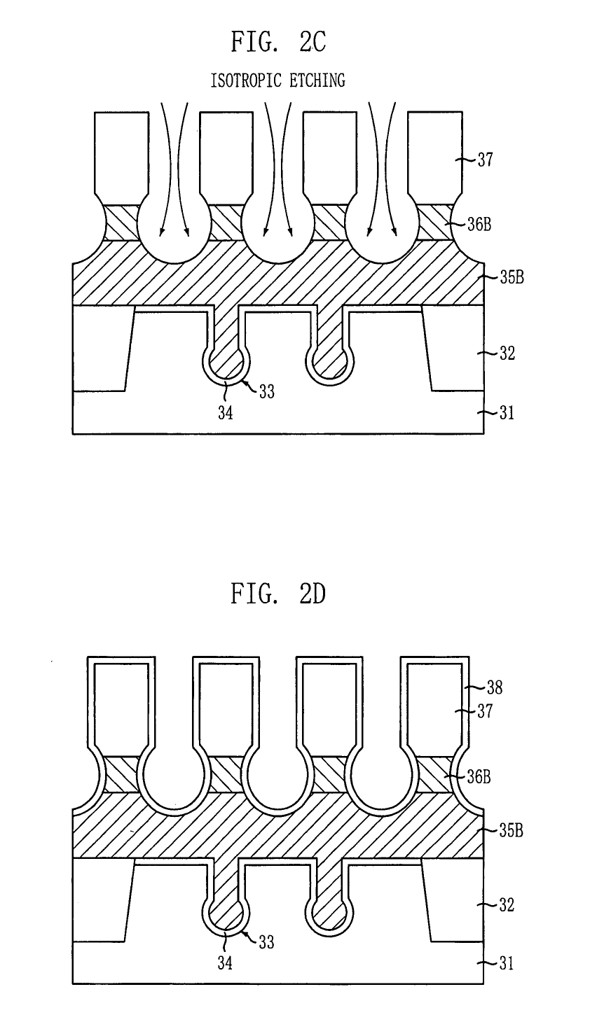

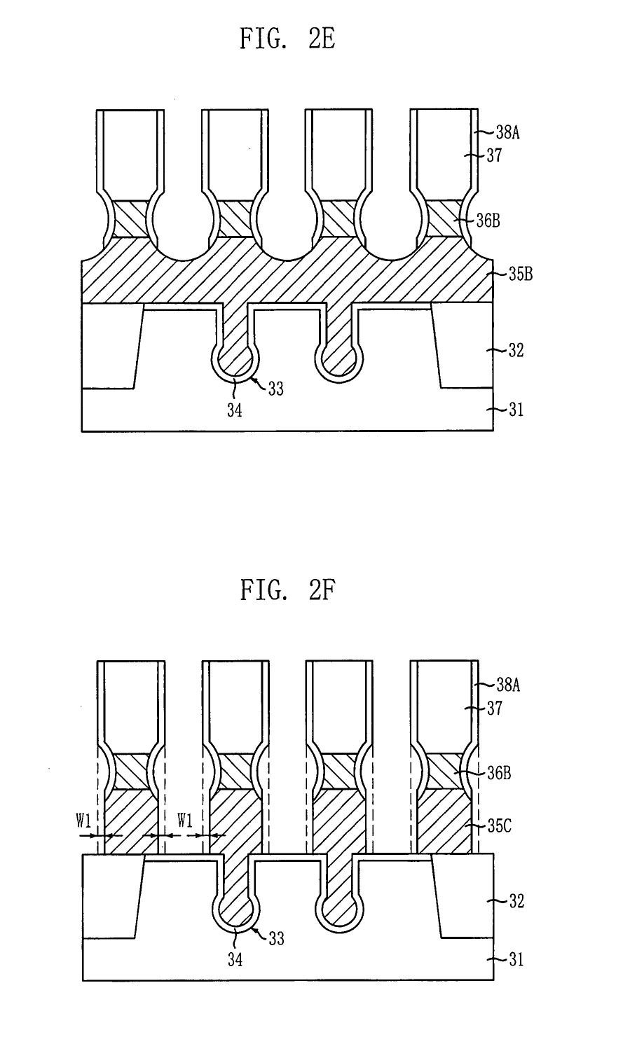

FIGS. 2A to 2F illustrate a method for fabricating a semiconductor device in accordance with an embodiment of the present invention. As shown in FIG. 2A, an isolation structure 32 is formed in a substrate 31 to define an active region. In more detail about the formation of the isolation structure 32, trenches are formed in the substrate 31. An insulation layer fills the trenches and then, is planarized to form the isolation structure 32.

The substrate 31 is selectively etched to form a plurality of recessed channel regions 33. The recessed channel regions 33 increase a channel length, thereby obtaining a refresh characteristic. Particularly, the recessed channel regions 33 include bulb-shaped recesses of which bottom portions are wider and more rounded than top portions. This structural configuration makes it possible to increase the channel length of the recessed channel regions 33 to a greater extent than the conventional structural configuration.

A gate insulation layer 34 is formed over the resulting structure including the recessed channel regions 33. The gate insulation layer 34 includes an oxide-based layer to insulate subsequent gate structures from the recessed channel regions 33.

A first electrode layer 35 of which a first portion fills the recessed channel regions 33 and a second portion projects over the substrate 31 is formed over the gate insulation layer 34. The first electrode layer 35 includes polysilicon layer, and will be referred to as a polysilicon layer hereinafter. The polysilicon layer 35 maintains a high quality of the gate insulation layer 34. Also, the polysilicon layer 35 reduces a disadvantage for resistance that may be generated when metal electrodes are formed directly over the gate insulation layer 34.

A second electrode layer 36 is formed over the polysilicon layer 35. The second electrode layer 36 includes a metal such as tungsten. The second electrode layer 36 will be referred to as a metal electrode layer herein below.

Although not shown, a gate hard mask layer is formed over the metal electrode layer 36 and then, the gate hard mask layer is patterned to form a gate hard mask 37. The gate hard mask layer includes a nitride-based material. In more detail about the formation of the gate hard mask 37, a photoresist layer is formed over the gate hard mask layer and then, subjected to photolithography. As a result, a photoresist pattern is formed. The gate hard mask layer (i.e., the nitride-based layer) is etched using the photoresist pattern to form the gate hard mask 37.

As shown in FIG. 2B, the metal electrode layer 36 is anisotropically etched to form a plurality of first metal electrodes 36A. The metal electrode layer 36 is patterned to have a vertical profile by the anisotropic etching. A portion of the polysilicon layer 35 is also excessively etched during the anisotropic etching. Reference numeral 35A identifies a first polysilicon layer which is excessively etched during the anisotropic etching.

The anisotropic etching uses a top power ranging from about 400 W to 800 W, and a bottom power ranging from about 50 W to 120 W. Also, the anisotropic etching uses a mixture gas including nitrogen trifluoride (NF₃), chlorine (Cl₂), helium (He), and nitrogen (N₂). A flow rate of NF₃ ranges from about 30 sccm to 80 sccm, and a flow rate of Cl₂ ranges from about 10 sccm to 50 sccm.

Typically, a passivation layer is formed over the resulting structure including the first metal electrodes 36A obtained after performing the anisotropic etching. However, according to the present embodiment, an isotropic etching is additionally performed to change a profile of the sidewalls of the first metal electrodes 36A. As a result, it is possible to prevent an excessive increase in widths of subsequent polysilicon electrodes.

As shown in FIG. 2C, the aforementioned isotropic etching is performed on the first metal electrodes 36A. In particular, the isotropic etching is targeted to etch the sidewalls of the first metal electrodes 36A, so that second metal electrodes 36B whose sidewalls are recessed are formed.

The isotropic etching uses a top power without a bottom power or both of the top power and the bottom power. The top power ranges from about 200 W to 500 W, and the bottom power ranges from about 1 W to 20 W. The bottom power used in the isotropic etching is lower than the bottom power used in the anisotropic etching.

The isotropic etching is performed in situ substantially in the same chamber where the anisotropic etching is performed. Also, the isotropic etching uses substantially the same etch gas used in the anisotropic etching illustrated in FIG. 2B. In other words, the isotropic etching uses a mixture gas including NF₃, Cl₂, He, and N₂. A flow rate of NF₃ ranges from about 30 sccm to 80 sccm, and a flow rate of Cl₂ ranges from about 10 sccm to 50 sccm.

If the isotropic etching is performed using the top power while not using or using a low level of the bottom power, ions of a plasma that are lightweight but have high energy cannot reach the surface of the first polysilicon layer 35A because of the low bottom power. Rather, the ions are distributed over the sidewalls of the first metal electrodes 36A and thus, etch the sidewalls of the first metal electrodes 36A. Heavy radical ions of the plasma that perform a chemical etch are distributed over the first polysilicon layer 35A and thus, etch a top portion of the first polysilicon layer 35A. Reference numeral 35B identifies the polysilicon layer patterned by the isotropic etching, and will be referred to as a second polysilicon layer hereinafter.

The isotropic etching is performed over the sidewalls of the first metal electrodes 36A faster than over the first polysilicon layer 35A below the first metal electrodes 36A. As a result, the sidewalls of the first metal electrodes 36A are recessed in a round form. Adjusting the conditions of the isotropic etching accelerates a recessing degree. Consequently, the second metal electrodes 36B can be controlled to have widths smaller than the width of the gate hard mask 37.

As shown in FIG. 2D, a passivation layer 38 is formed over the above resulting structure illustrated in FIG. 2C. The passivation layer 38 includes a nitride-based layer, and prevents damage on the second metal electrodes 36B when the second polysilicon layer 35A is etched and abnormal oxidation of the second metal electrodes 36B during subsequent re-oxidation of gate structures.

As shown in FIG. 2E, an etch-back process is performed to remove a portion of the passivation layer 38 disposed on top of the gate hard mask 37 and the second polysilicon layer 35B. As a result, the passivation layer 38 remains the sidewalls of the second metal electrodes 36B and the gate hard mask 37. Reference numeral 38A identifies the passivation layer patterned by the etch-back process.

As shown in FIG. 2F, a portion of the second polysilicon layer 35B exposed after the above etch-back process is etched to form polysilicon electrodes 35C. Since the second polysilicon layer 35B is etched under the state in which the patterned passivation layer 38A is formed on the recessed sidewalls of the second metal electrodes 36B, the widths of the polysilicon electrodes 35C are larger than those of the second metal electrodes 36B, but smaller than those of the conventional polysilicon electrodes. Reference letter W1 illustrates how much the widths of the polysilicon electrodes 35C are decreased compared to the widths of the conventional polysilicon electrodes.

The portion of the patterned passivation layer 38A formed on the sidewalls of the second metal electrodes 36B is positioned more inside than the portion of the patterned passivation layer 38A formed on the sidewalls of the gate hard mask 37. Thus, the portion of the patterned passivation layer 38A formed on the sidewalls of the second metal electrodes 36B is not damaged when the second polysilicon layer 35B is etched. When the second polysilicon layer 35B is etched, although the portion of the patterned passivation layer 38A formed on the sidewalls of the gate hard mask 37 may be partially damaged, the portion of the patterned passivation layer 38A formed on the sidewalls of the second metal electrodes 36B is not damaged. Hence, compared with the conventional patterned passivation layer, the patterned passivation layer 38A is formed with a reduced thickness on the sidewalls of the second metal electrodes 36B. The patterned passivation layer 38A formed thinner than before permits the reduction in the widths of the polysilicon electrodes 35C.

Therefore, since the widths of the polysilicon electrodes 35C can be reduced, gate structures each including the polysilicon electrode 35C, the second metal electrode 36B and the gate hard mask 37 can achieve a sufficient open margin of subsequent landing plug contacts and prevent abnormal oxidation of the second metal electrodes 36B.

In the illustrated embodiment, the anisotropic etching and isotropic etching are performed sequentially on the metal electrode layer 36 to form the second metal electrodes 36B with the recessed sidewalls. The patterned passivation layer 38A is formed on the recessed sidewalls of the second metal electrodes 36B. As a result, a sufficient open margin for an etching of forming subsequent landing plug contacts can be obtained, and the second metal electrodes 36B is not be abnormally oxidized.

The recessed sidewalls of the second metal electrodes 36B prevent damage on the lateral portion of the patterned passivation layer 38A when the second polysilicon layer 35B is etched. Thus, the passivation layer 38 can be formed more thinly than the conventional passivation layer.

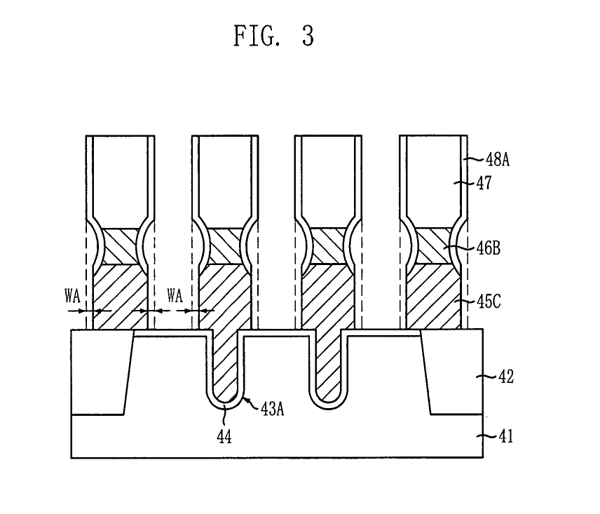

FIG. 3 illustrates a gate structure of a semiconductor device in accordance with another embodiment of the present invention. According to the other embodiment of the present invention, U-shaped recessed channel regions 43A are provided. Except for the U-shaped recessed channel regions 43A, the rest of the illustrated elements are formed by performing substantially the same processes illustrated in FIGS. 2A to 2F. Thus, detailed description thereof will be omitted. Although not explained in detail, reference numerals 48A, 47, 46B, 45C, 44, 42, and 41 identify a pattered passivation layer, a gate hard mask, a second metal electrode, a polysilicon electrode, a gate insulation layer, an isolation structure, and a substrate, respectively. Reference letter WA illustrates how much the widths of the polysilicon electrodes 45C are decreased compared to the widths of the conventional polysilicon electrodes.

According to the embodiments of the present invention, the sidewalls of the metal electrodes are recessed, and the passivation layer is formed thereon. Thus, the lateral portion of the passivation layer is not likely to be etched or damaged during the etching of forming the polysilicon electrodes. Consequently, compared with the conventional passivation layer, the passivation layer can be formed thinner. This effect contributes to reducing the widths of the polysilicon electrodes. Accordingly, an opening margin of subsequent landing plug contacts can be increased. Also, even if the thickness of the passivation layer is reduced, abnormal oxidation of the metal electrodes does not occur due to the recessed sidewalls of the metal electrodes. Accordingly, the gate structures are formed with an increased open margin for an etching of forming subsequent landing plug contacts while not abnormally oxidizing the metal electrodes.

While the present invention has been described with respect to the specific embodiments, it will be apparent to those skilled in the art that various changes and modifications may be made without departing from the spirit and scope of the invention as defined in the following claim.

What is claimed is:

1. A method for fabricating a semiconductor device, comprising:
forming an insulation layer, a first electrode layer, a second electrode layer, and a hard mask over a substrate;
etching the second electrode layer to form second electrodes with recessed sidewalls;
forming a passivation layer over a resultant surface profile provided after forming the second electrodes;
performing an etch-back process on the passivation layer; and
etching the first electrode layer exposed by the etch-back process to form first electrodes.

2. The method of claim 1, wherein etching the second electrode layer comprises performing an anisotropic etching and an isotropic etching in sequence.

3. The method of claim 2, wherein performing the anisotropic etching and the isotropic etching proceeds in situ substantially in the same chamber.

4. The method of claim 3, wherein performing the anisotropic etching and the isotropic etching comprises applying a top power and a bottom power simultaneously, the bottom power of the isotropic etching is lower than that of the anisotropic etching.

5. The method of claim 4, wherein performing the anisotropic etching comprises using a top power ranging from about 400 W to 800 W and a bottom power ranging from about 50 W to 120 W.

6. The method of claim 4, wherein the performing isotropic etching comprises using a top power ranging from about 200 W to 500 W and a bottom power ranging from about 1 W to 20 W.

7. The method of claim 3, wherein performing the anisotropic etching comprises applying a top power and a bottom power simultaneously, and performing the isotropic etching comprises applying a top power.

8. The method of claim 7, wherein performing the anisotropic etching comprises using a top power ranging from about 400 W to 800 W and a bottom power ranging from about 50 W to 120 W.

9. The method of claim 7, wherein performing the isotropic etching comprises using a top power ranging from about 200 W to 500 W.

10. The method of claim 2, wherein performing the anisotropic etching and the isotropic etching comprises using substantially the same etch gas.

11. The method of claim 10, wherein the etch gas comprises a mixture gas including nitrogen trifluoride (NF₃), chlorine (Cl₂), helium (He), and nitrogen (N₂).

12. The method of claim 11, wherein a flow rate of NF₃ ranges from about 30 sccm to 80 sccm, and a flow rate of Cl₂ ranges from about 10 sccm to 50 sccm.

13. The method of claim 1, wherein the second electrode layer comprises a metal, the metal comprising tungsten.

14. The method of claim 1, wherein the hard mask and the passivation layer comprise a nitride-based material.

15. The method of claim 1, wherein the second electrodes with the recessed sidewalls have a width smaller than the hard mask.

16. The method of claim 1, further comprising, prior to forming the insulation layer, the first electrode layer, the second electrode layer, and the hard mask over the substrate, forming recessed channel regions in the substrate.

17. The method of claim 16, wherein forming the first electrode layer comprises forming a portion of the first electrode layer to fill the recessed channel regions.

18. The method of claim 1, wherein the first electrode layer comprises polysilicon.

19. The method of claim 15, wherein the recessed channel regions are formed in one of a bulb-shape and a U-shape.
